(19) United States
(12) Patent Application Publication
(10) Pub. No.: US 2020/0243484 A1
(43) Pub. Date: Jul. 30, 2020

(54) RADIO FREQUENCY (RF) SWITCH DEVICE INCLUDING RF SWITCH INTEGRATED CIRCUIT (IC) DIVIDED BETWEEN SIDES OF PCB

(71) Applicant: Avago Technologies International Sales Pte. Limited, Singapore (SG)

(72) Inventors: Hyungchul Kim, Gyeonggi-do (KR); Hyung-bin Lee, Seoul (KR)

(21) Appl. No.: 16/262,120

(22) Filed: Jan. 30, 2019

(51) Int. Cl. H01L 25/065; H01L 23/538; H01L 23/498

(52) U.S. Cl. CPC H01L 25/0657; H01L 23/5384; H01L 23/5386; H01L 23/49816; H01L 24/16; H01L 2225/06548; H01L 2225/06572; H01L 2225/06586; H01L 2225/06517

(57) ABSTRACT

A radio frequency (RF) switch device includes a printed circuit board (PCB) having a first side and a second side opposite the first side, at least one pole connection on each of the first side and the second side of the PCB, and at least one throw connection on each of the first side and the second side of the PCB. The RF switch device further includes a first switch integrated circuit (IC) including at least one first switching element for selectively connecting the at least one pole connection and the at least one throw connection on the first side of the PCB, and a second switch IC including at least one second switching element for selectively connecting the at least one pole connection and the at least one throw connection on the second side of the PCB.

### BACKGROUND

Radio frequency (RF) wireless communication devices, such as cellular telephones, personal communication devices and portable computers, include printed circuit boards (PCBs) with various components, including RF switches, for example. The structure of a typical RF switch module (device) is becoming increasingly complicated in order to support multi-mode and multi-band wireless communication systems.

An RF switch module includes one or more poles and one or more throws, depending on circuit design. For example, an RF switch may be described as nPmT RF switch, which has n-poles and m-throws, where n and m are each positive integers. In a solid state circuit, to position each throw to enable connecting to one or more poles in the nPmT RF switch, lines are routed on a PCB. However, as the size of the circuit constituting the nPmT switch increases, the number of routing lines of the PCB increases, and the lengths of the routing lines become longer. Generally, longer routing lines result in additional insertion loss, increase parasitic capacitance and/or inductance, and otherwise degrade overall performance of the RF switch module.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified cross-section of a module having a multilayer printed circuit board (PCB) including a component inside a cavity, according to a representative embodiment.

FIG. 2A is a simplified cross-sectional view of an RF switch module for an illustrative single-pole, multi-throw switch, including an RF switch integrated circuit (IC) divided between top and bottom sides of the PCB, respectively, according to a representative embodiment.

FIG. 2B is a simplified circuit diagram showing potential switch element configurations for first and second switch ICs of the divided RF switch IC, according to a representative embodiment.

FIG. 3A is a simplified cross-sectional view of an RF switch module for an illustrative double-pole, multi-throw switch, including an RF switch IC divided between top and bottom sides of the PCB, according to a representative embodiment.

FIG. 3B is a simplified circuit diagram showing potential switch element configurations for first and second switch ICs of the divided RF switch IC, according to a representative embodiment.

FIG. 4A is a simplified cross-sectional view of an RF switch module for an illustrative double-pole, multi-throw switch, including an RF switch IC divided between top and bottom sides of the PCB, according to a representative embodiment.

FIG. 4B is a simplified circuit diagram showing potential switch element configurations for first and second switch ICs of the divided RF switch IC, according to a representative embodiment.

FIG. 5A is a simplified cross-sectional view of an RF switch module for an illustrative double-pole, multi-throw switch, including an RF switch IC divided between top and bottom sides of the PCB, according to a representative embodiment.

FIG. 5B is a simplified circuit diagram showing potential switch element configurations for first and second switch ICs of the divided RF switch IC, according to a representative embodiment.

FIG. 6A is a simplified cross-sectional view of an RF switch module for an illustrative three-pole, multi-throw switch, including an RF switch IC divided between top and bottom sides of the PCB, according to a representative embodiment.

FIG. 6B is a simplified circuit diagram showing potential switch element configurations for first and second switch ICs of the divided RF switch IC, according to a representative embodiment.

FIG. 7A is a simplified cross-sectional view of an RF switch module for an illustrative three-pole, multi-throw switch, including an RF switch IC divided between top and bottom sides of the PCB, according to a representative embodiment.

FIG. 7B is a simplified circuit diagram showing potential switch element configurations for first and second switch ICs of the divided RF switch IC, according to a representative embodiment.

FIG. 8A is a simplified cross-sectional view of an RF switch module for an illustrative four-pole, multi-throw switch, including an RF switch IC divided between top and bottom sides of the PCB, according to a representative embodiment.

FIG. 8B is a simplified circuit diagram showing potential switch element configurations for first and second switch ICs of the divided RF switch IC, according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is understood that the drawings and the various elements depicted therein are not drawn to scale. Further, relative terms, such as “above,” “below,” “top,” “bottom,” “upper,” “lower,” “first,” and “second” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

As used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As used in the specification and the appended claims and in addition to its ordinary meaning, the term “approximately” means to within an acceptable limit or amount to one having ordinary skill in the art. For example, “approximately the same” means that one of ordinary skill in the art would consider the items being compared to be the same.

Generally, according to various embodiments, an RF switch module or device includes a printed circuit board (PCB) and a switch integrated circuit (IC) with nPmT structure divided into two portions, a first switch IC and a second switch IC, assembled on top and bottom sides of the PCB, respectively. One or more of the throws and/or poles that need to be accessed by both the first and second switch ICs (on both sides of the PCB) are connected or wired concisely by corresponding through vias of the PCB. This double-sided RF switch module reduces or minimizes insertion loss that would otherwise be caused by routing lines of the PCB. In addition, the double-sided RF switch module helps to reduce size by reducing the footprint of the switch IC on the top side of the PCB, where most components are attached in conventional RF switch modules. The double-sided RF switch module may be applied to single-pole, multi-throw switches, as well as multi-pole, multi-throw switches.

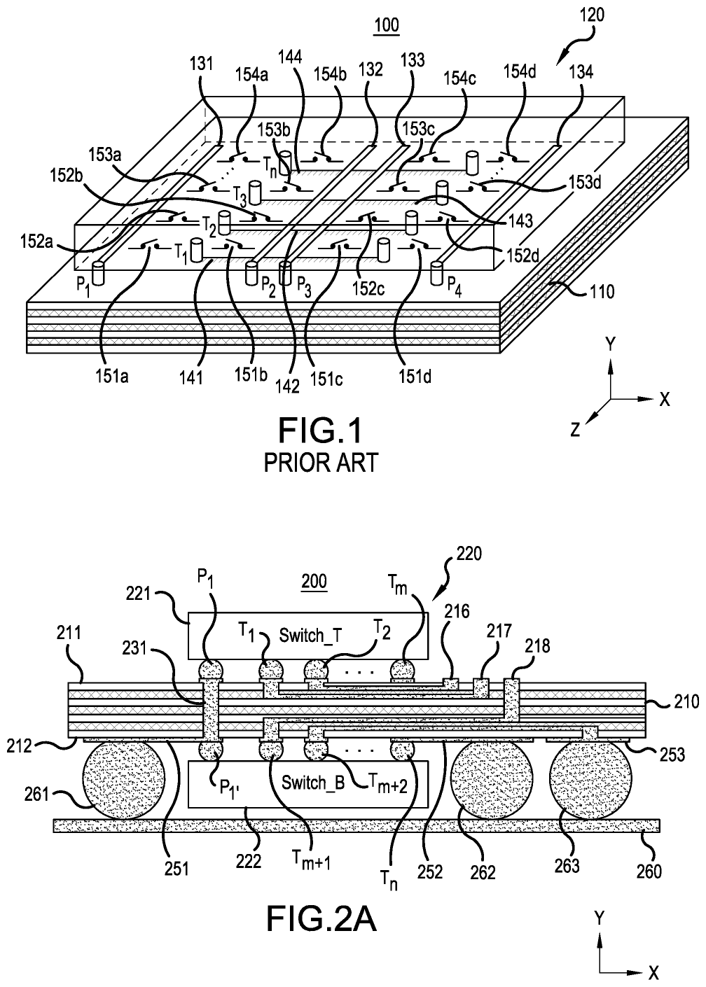

FIG. 1 is a simplified top perspective view of an example of a conventional RF switch module including a multilayer PCB.

Referring to FIG. 1, conventional RF switch module 100 includes a PCB 110 and a switch IC 120 formed on a top side (surface) of the PCB 110. In the depicted example, the RF switch module 100 is a 4PnT (four pole, n throw) switch, where n is a positive integer. More particularly, the switch IC 120 includes a first pole connection P1 connected to a first pole line 131, a second pole connection P2 connected to a second pole line 132, a third pole connection P3 connected to a third pole line 133, and a fourth pole connection P4 connected to a fourth pole line 134. In addition, the switch IC 120 includes a first throw connection T1 connected to a first routing line 141 between two first throw connection T1 terminals, a second throw connection T2 connected to a second routing line 142 between two second throw connection T2 terminals, a third throw connection T3 connected to a third routing line 143 between two third throw connection T3 terminals, and an nth throw connection Tn connected to a fourth routing line 144 between two nth throw connection Tn terminals.

In addition, the switch IC 120 includes a number of switch elements (switches) that are operable to selectively connect one or more of the first to nth throw connections T1 to Tn to one or more of the first to fourth pole connections P1 to P4, respectively, depending on the desired circuit connectivity. In the depicted example, the first throw connection T1 is selectively connectable using one or more of switch elements 151a to 151d, the second throw connection T2 is selectively connectable using one or more of switch elements 152a to 152d, the third throw connection T3 is selectively connectable using one or more of switch elements 153a to 153d, and the fourth throw connection Tn is selectively connectable using one or more of switch elements 154a to 154d. So, for example, the first throw connection T1 may be connected to the first pole connection P1 by closing the switch element 151a, may be connected to the second pole connection P2 by closing the switch element 152a, may be connected to the third pole connection P3 by closing the switch element 153a, and may be connected to the fourth pole connection P4 by closing the switch element 154a. In this manner, the first throw connection T1 may be selectively connected to any combination of none to all of the first to fourth pole connections P1 to P4. This also applies to the selective connectivity of the second to nth throw connections T2 to Tn to any or all of the first to fourth pole connections P1 to P4.

As can be seen in FIG. 1, the first to nth routing lines 141 to 144 are traces formed on the top side of the PCB 110. Accordingly, the first to nth routing lines 141 to 144 physically occupy space on the PCB 110 (e.g., which may be used for other electrical components). The occupied space must also account for arrangement and spacing of the first to fourth pole connections P1 to P4, the first to nth throw connections T1 to Tn, and the switching elements 151a-151d, 152a-152d, 153a-153d, and 154a-154d to avoid unwanted coupling among them. As mentioned above, as the size of the switch IC 120 increases, the lengths of the first to fourth routing line 141 to 144 of the PCB 110 become longer, e.g., increasing insertion loss, parasitic capacitance, inductance and/or unwanted coupling, and degrading overall performance of the RF switch module 100.

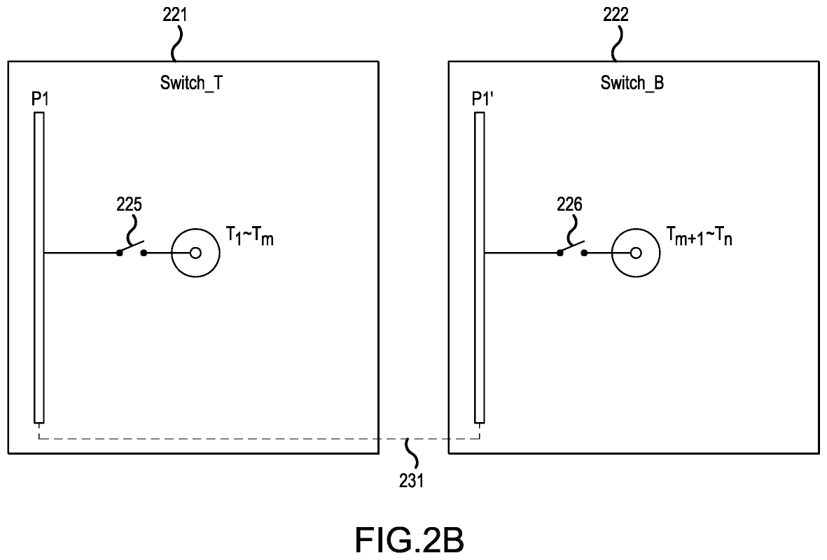

FIG. 2A is a simplified cross-sectional view of an RF switch module for an illustrative single-pole, multi-throw switch, including an RF switch integrated circuit (IC) divided between top and bottom sides of the PCB, according to a representative embodiment. FIG. 2B is a simplified circuit diagram showing potential switch element configurations for first and second switch ICs of the divided RF switch IC, according to a representative embodiment.

Referring to FIG. 2A, RF switch module 200 includes a multiple layer PCB 210 and a single-pole, multi-throw RF switch IC 220, which is divided into two portions including a first switch IC 221 (Switch_T) arranged on a first side 211 (e.g., top surface) of the PCB 210 and a second switch IC 222 (Switch_B) arranged on a second side 212 (e.g., bottom surface) of the PCB 210, opposite the first side 211. Each of the first switch IC 221 and the second switch IC 222 is likewise a single-pole, multi-throw switch, as described below. The first switch IC 221 and the second switch IC 222 (as well as each switch IC of the various embodiments discussed herein) may be covered by a molded compound (not shown) that provides a hermetical seal and protects against environmental elements, such as temperature and moisture. The PCB 210 (as well as each multiple layer PCB of the various embodiments discussed herein) may include multiple layers of electrically conductive material separated by multiple layers of insulating material. The electrically conductive material may include copper (Cu), aluminum (Al), gold (Au) and/or silver (Ag), for example. The insulating material may include prepreg material and/or resin-based dielectric material, for example.

The RF switch module 200 may be connected to additional circuitry, such as system mother board 260, for example. That is, the RF switch module 200 may be a ball grid array (BGA) component, for example, that includes an array of solder balls, indicated by representative solder balls 261, 262 and 263, which are attached to a bottom layer of the PCB 210 via illustrative second pads 251, 252 and 253 (discussed below), respectively. In various embodiments, the solder balls 261, 262 and 263 are located at the sides of the second switch IC 222, and not below the second switch IC 222, for example. Alternatively, the RF switch module 200 may be a land grid array (LGA) component (which does not include the array of solder balls), for example, or various other types of components, without departing from the scope of the present teachings.

In the depicted embodiment, the single-pole is provided by a first pole connection P1 on the first side 211 and another first pole connection P1′ on the second side 212 of the PCB 210, electrically connected by a pole-via 231 passing through the PCB 210 between the first pole connection P1 and the another pole connection P1′. The pole-via 231 (as well as each pole-via of the various embodiments discussed herein) is a through via formed of electrically conductive material, such as copper (Cu), aluminum (Al), gold (Au) and/or silver (Ag), for example.

In the depicted embodiment, the first pole connections P1, P1′ are physically aligned with one another (e.g., aligned in the y direction, as indicated by the coordinate system shown in FIG. 2A) on the first and second sides 211 and 212 of the PCB 210, and the pole-via 231 is effectively a straight line. In this manner, the first pole connections P1, P1′ are arranged in the closest position with respect to one another, while on opposite sides of the PCB 210, and the pole-via 231 accordingly has its shortest length (e.g., about the thickness of the PCB 210). Thus, the pole-via 231 is shorter than the pole line 131, for example, in the conventional RF switch module 100. This lowers or reduces insertion loss, parasitic capacitance, parasitic inductance, and/or unwanted coupling. The first switch IC 221 and the second switch IC 222 may likewise be substantially aligned with one another, for example, to enable alignment of the first pole connections P1, P1′, although the first pole connections P1, P1′ may be aligned regardless of whether the first switch IC 221 and the second switch IC 222 are substantially aligned with one another. The same is true for the first and second switch ICs in each of the various embodiments.

In alternative embodiments, the first pole connections P1, P1′ may not be vertically aligned with one another, thereby increasing the distance between the first pole connections P1, P1′ and lengthening the pole-via 231, without departing from the scope of the present teachings. That is, the pole-via 231 may still be shorter than the pole line 131, for example, in FIG. 1, even when the first pole connections P1, P1′ are not aligned.

Further, in the depicted embodiment, the multiple throws are provided by one or more throw connections on each of the first and second sides 211 and 212 of the PCB 210. For example, the RF switch module 200 may have a total of n throw connections, indicated by representative m throw connections T1, T2 . . . Tm on the first side 211 and additional throw connections Tm+1, Tm+2 . . . Tn on the second side 212 of the PCB 210, where m is a positive integer greater than or equal to 1 and n is a positive integer greater than or equal to 2. In the depicted embodiment, none of the throw connections are connected to one another by through vias through the PCB 210. Rather, each of the throw connections T1, T2 . . . Tm on the first side 211 are connected to first pads 216, 217 and 218 on the first side 211, respectively. The first pads 216, 217 and 218 are available for providing electrical and/or mechanical connections to various electrical components, such as dies, surface mounted technology (SMT) components, and the like, as would be apparent to one skilled in the art. Each of the throw connections Tm+1, Tm+2 . . . Tn on the second side 212 are connected to second pads 251, 252 and 253 on the second side 212, respectively. The second pads 251, 252 and 253 may be connected to the solder balls 261, 262 and 263, for example. In the depicted embodiment (as well as in the other embodiments discussed herein), the solder balls 261, 262 and 263 are arranged beside the second switch IC 222, e.g., to connected directly to the PCB 210, as opposed to below the second switch IC 222 itself. This provides reliable electrical and mechanical contact between the solder balls 261, 262 and 263 and the RF switch module 200. The first pads 216, 217 and 218 and the second pads 251, 252 and 253 are formed of electrically conductive material, such as copper (Cu), aluminum (Al), gold (Au) and/or silver (Ag), for example.

The first switch IC 221 of the divided RF switch IC 220 includes first switching elements for selectively connecting the throw connections T1, T2 . . . Tm to the first pole connection P1, and the second switch IC 222 includes second switching elements for selectively connecting the throw connections Tm+1, Tm+2 . . . Tn to the other first pole connection P1′. Referring to FIG. 2B, the potential switch element configuration for each of the throw connections T1, T2 . . . Tm of the first switch IC 221 is shown by representative switch element 225, which selectively connects each of the throw connections T1, T2 . . . Tm to the first pole connection P1. Similarly, the potential switch element configuration for each of the throw connections Tm+1, Tm+2 . . . Tn of the second switch IC 222 is shown by representative switch element 226, which selectively connects each of the throw connections Tm+1, Tm+2 . . . Tn to the other first pole connection P1′. The first pole connections P1, P1′ are connected by the pole-via 231, indicated by a dashed line.

Notably, for the sake of convenience, only one switch element 225 is shown in the first switch IC 221, and only one switch element 226 is shown in the second switch IC 222. However, it is understood that each of the throw connections T1, T2 . . . Tm in the first switch IC 221 is connectable to the first pole connection P1 by a corresponding switch element 225, and that each of the throw connections Tm+1, Tm+2 . . . Tn in the second switch IC 222 is connectable to the other first pole connection P r by a corresponding switch element 226.

In each of the various embodiments discussed herein (FIGS. 2A to 8B), the switch elements (e.g., switch elements 225 and 226) may be operable under control of a controller (not shown), such as one or more computer processors, application specific integrated circuits (ASICs), field-programmable gate arrays (FPGAs), or combinations thereof, using software, firmware, hard-wired logic circuits, or combinations thereof. A processor, in particular, may be constructed of any combination of hardware, firmware or software architectures, and may include its own memory (e.g., nonvolatile memory) for storing executable software/firmware executable code that allows it to perform the various functions. In an embodiment, the computer processor may comprise a central processing unit (CPU), for example, executing an operating system.

Memory (not shown) may be provided to store software and/or programs executable by the processor(s), as well as data, such as predetermined switch settings for various circuit configurations. The memory may be implemented by any number, type and combination of random access memory (RAM) and read-only memory (ROM), for example, and may store various types of information, such as computer programs and software algorithms executable by the one or more processors (and/or other components), as well as data, for example. The various types of ROM and RAM may include any number, type and combination of computer readable storage media, such as a hard disk drive, a solid state hard disk, flash memory, a universal serial bus (USB) drive, electrically programmable read-only memory (EPROM), electrically erasable and programmable read only memory (EEPROM), a CD, a DVD, an optical disk, a floppy disk, a magneto-optical disk, the register file of the processor, and the like, which are tangible and non-transitory storage media (e.g., as compared to transitory propagating signals). The term computer readable-storage medium also refers to various types of recording media capable of being accessed via a network or communication link. For example, data may be retrieved over a modem, over the internet, or over a local area network.

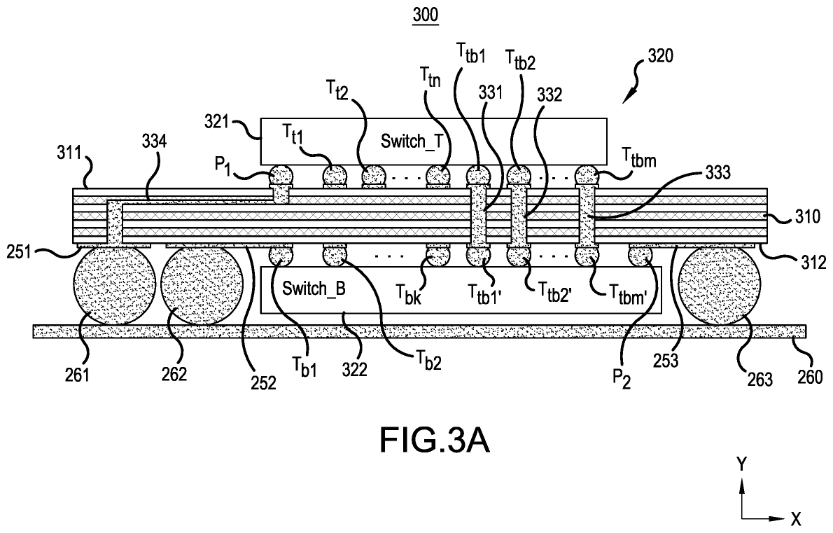

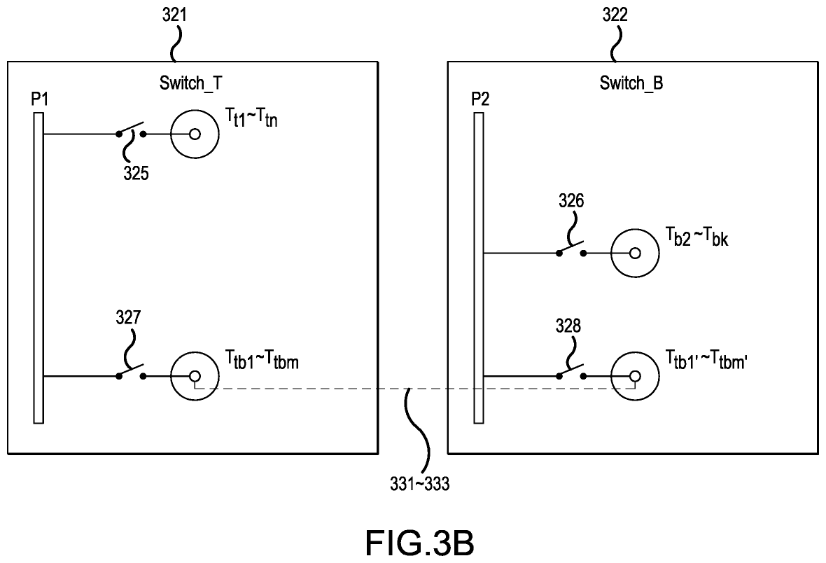

FIG. 3A is a simplified cross-sectional view of an RF switch module for an illustrative double-pole, multi-throw switch, including an RF switch IC divided between top and bottom sides of the PCB, according to a representative embodiment. FIG. 3B is a simplified circuit diagram showing potential switch element configurations for first and second switch ICs of the divided RF switch IC, according to a representative embodiment.

Referring to FIG. 3A, RF switch module 300 includes a multiple layer PCB 310 and a double-pole, multi-throw RF switch IC 320, which is divided into two portions including a first switch IC 321 arranged on a first side 311 (e.g., top surface) of the PCB 310 and a second switch IC 322 arranged on a second side 312 (e.g., bottom surface) of the PCB 310, opposite the first side 311. Each of the first switch IC 321 and the second switch IC 322 is a single-pole, multi-throw switch, as described below. The RF switch module 300 may be connected to additional circuitry, such as system mother board 260, for example. That is, the RF switch module 300 may be a BGA component, attached to the system mother board 260 by an array of solder balls, indicated by representative solder balls 261, 262 and 263, or an LGA component, for example, or other type of component.

In the depicted embodiment, the double-pole is provided by a first pole connection P1 on the first side 311 and a second pole connection P2 on the second side 312 of the PCB 310. Neither the first pole connection P1 nor the second pole connection P2 is electrically connected to the opposite side of the PCB 310 by a through via. The first pole connection P1 is connected to the second pad 251 by a pole-via 334 passing through the PCB 310, and the second pole connection P2 is connected to the second pad 253 for the sake of illustration.

Further, in the depicted embodiment, the multiple throws are provided by one or more throw connections on each of the first and second sides 311 and 312 of the PCB 310, including one or more isolated throw connections on only the first or second side 311 or 312, and one or more linked throw connections having throw connections on both the first and second sides 311 and 312 joined through the PCB 310 by throw-vias, respectively. For example, the RF switch module 300 may have representative throw connections Tt1, Tt2 . . . Ttn and Ttb1, Ttb2 . . . Ttbm on the first side 311 and additional throw connections Tb1, Tb2 . . . Tbk and Ttb1′, Ttb2′ . . . Ttbm′ on the second side 312 of the PCB 310, where each of m, n and k is a positive integer greater than or equal to 1.

In the depicted embodiment, none of the throw connections Tt1, Tt2 . . . Ttn and Tb1, Tb2 . . . Tbk is connected to another throw connection by a through via in the PCB 310. Also, the throw connection Tb1 may be connected to the pad 252. However, the throw connection Ttb1 is connected to the other throw connection Ttb1′ by a throw-via 331, the throw connection Ttb2 is connected to the other throw connection Ttb2′ by a throw-via 332, and the throw connection Ttbm is connected to the other throw connection Ttbm′ by a throw-via 333, for example. More or fewer throw connections may be included on the first side 311 and/or the second side 312 of the PCB 310, and the number of throw connections on the first and second sides 311 and 312 may different from one another, without departing from the scope of the present teachings. In the depicted embodiment, the throw connections Tt1, Tt2 . . . Ttn and Ttb1, Ttb2 . . . Ttbm on the first side 311 and additional throw connections Tb1, Tb2 . . . Tbk and Ttb1′, Ttb2′ . . . Ttbm′ on the second side 312, connecting the first and second switch ICs 321 and 322 by the throw-vias 331, 332 and 333 are in the center portion rather than on the outer portions of the first and second switch ICs 321 and 322, while the first pole connection P1 and the second pole connection P2 are on the outer portions to connect to the solder balls 262 and 263, respectively. Also, the throw-vias 331, 332 and 333 (as well as each throw-via of the various embodiments discussed herein) is a through via formed of electrically conductive material, such as copper (Cu), aluminum (Al), gold (Au) and/or silver (Ag), for example.

In the depicted embodiment, the throw connections Ttb1, Ttb1′ are physically aligned with one another (e.g., aligned in the y direction, as indicated by the coordinate system shown in FIG. 3A) on the first and second sides 311 and 312 of the PCB 310, and the throw-via 331 is effectively a straight line. In this manner, the throw connections Ttb1, Ttb1′ are arranged in the closest position with respect to one another, while on opposite sides of the PCB 310, and the throw-via 331 accordingly has its shortest length (e.g., about the thickness of the PCB 310). Thus, the throw-via 331 is shorter than the first routing line 141, for example, in the conventional RF switch module 100. This lowers or reduces insertion loss, parasitic capacitance, parasitic inductance, and/or unwanted coupling. In alternative embodiments, the throw connections Ttb1, Ttb1′ may not be vertically aligned with one another, thereby increasing the distance between the throw connections Ttb1, Ttb1′ and lengthening the throw-via 331, without departing from the scope of the present teachings. That is, the throw-via 331 may still be shorter than the first routing line 141, for example, in FIG. 1.

Likewise, in the depicted embodiment, the additional throw connections Ttb2, Ttb2′ and Ttbm, Ttbm′ are shown physically aligned with one another (e.g., aligned in the y direction), respectively, on the first and second sides 311 and 312 of the PCB 310, and the connecting throw-vias 332 and 333 are effectively straight lines. That is, the throw connections Ttb1, Ttb1′, Ttb2, Ttb2′ and Ttbm, Ttbm′ are connected vertically through the throw-vias 331, 332 and 333, respectively. Therefore, it is possible to minimize routing loss of the PCB 310 by connecting the facing throw connections to the shortest distance. However, each set of the throw connections Ttb2, Ttb2′ and Ttbm, Ttbm′ may be offset diagonally from one another, as discussed above, without departing from the scope of the present teachings.

The first switch IC 321 of the divided RF switch IC 320 includes first switching elements for selectively connecting the throw connections Tt1, Tt2 . . . Ttn to the first pole connection P1 on the first side 311, and for selectively connecting the throw connections Ttb1, Ttb2 . . . Ttbm to the first and second pole connections P1 and P2 on the first and second sides 311 and 312, respectively. Similarly, the second switch IC 322 of the divided RF switch IC 320 includes second switching elements for selectively connecting the throw connections Tb1, Tb2 . . . Tbn to the second pole connection P2 on the second side 312, and for selectively connecting the throw connections Ttb1,′ Ttb2′ . . . Ttbm′ to the first and second pole connections P1 and P2 on the first and second sides 311 and 312, respectively.

Referring to FIG. 3B, the potential switch element configurations for each of the throw connections Tt1, Tt2 . . . Ttn and the throw connections Ttb1, Ttb2 . . . Ttbm of the first switch IC 321 is shown by representative switch elements 325 and 327. The switch element 325 selectively connects the throw connections Tt1, Tt2 . . . Ttn to the first pole connection P1. Similarly, the switch element 326 selectively connects the throw connections Tb1, Tb2 . . . Tbk to the second pole connection P2. The switch elements 327 and 328 selectively connect the throw connections Ttb1, Ttb2 . . . Ttbm and Ttb1′, Ttb2′ . . . Ttbm′ to the first and second pole connections P1 and P2. The throw connections Ttb1, Ttb2 . . . Ttbm are connected to the throw connections Ttb1′, Ttb2′ . . . Ttbm′ by the throw-vias 331, 332 and 333, respectively, indicated by a single dashed line for ease of illustration.

Notably, for the sake of convenience, only one switch element 325 and only one switch element 327 are shown in the first switch IC 321, and only one switch element 326 and only one switch element 328 are shown in the second switch IC 322. However, it is understood that each of the throw connections Tt1, Tt2 . . . Ttn in the first switch IC 321 is connectable to the first pole connection P1 by a corresponding switch element 325, that each of the throw connections Ttb1, Ttb2 . . . Ttbm in the first switch IC 321 is connectable to the first pole connection P1 by a corresponding switch element 327, that each of the throw connections Tb1, Tb2 . . . Tbk in the second switch IC 322 is connectable to the second pole connection P2 by a corresponding switch element 326, and that each of the throw connections Ttb1′, Ttb2′ . . . Ttbm′ in the second switch IC 322 is connectable to the second pole connection P2 by a corresponding switch element 328. Of course, whenever the throw connections Ttb1, Ttb2 . . . Ttbm are connected to the first pole connection P1 by corresponding switch elements 327, the throw connections Ttb1′, Ttb2′ . . . Ttbm′ are likewise connected to the first pole connection P1 by way of the throw-vias 331, 332 and 333. Also, whenever the throw connections Ttb1′, Ttb2′ . . . Ttbm′ are connected to the second pole connection P2 by corresponding switch elements 328, the throw connections Ttb1, Ttb2 . . . Ttbm are likewise connected to the second pole connection P2 by way of the throw-vias 331, 332 and 333.

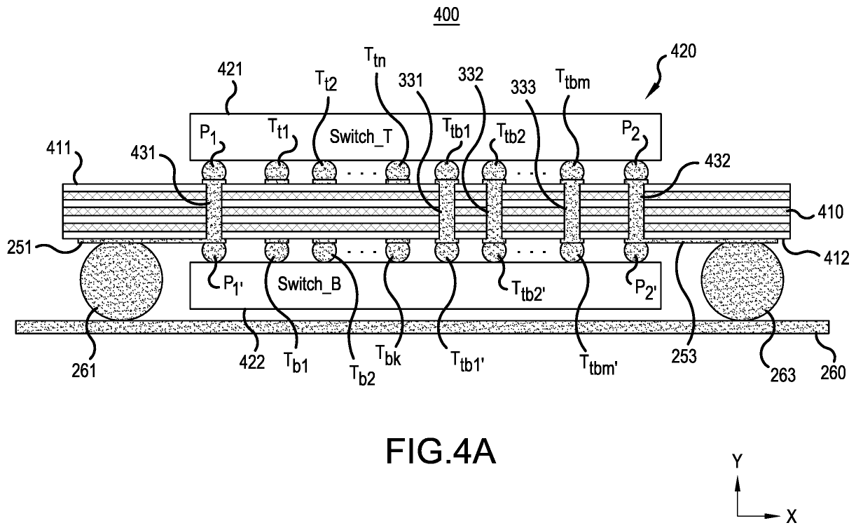

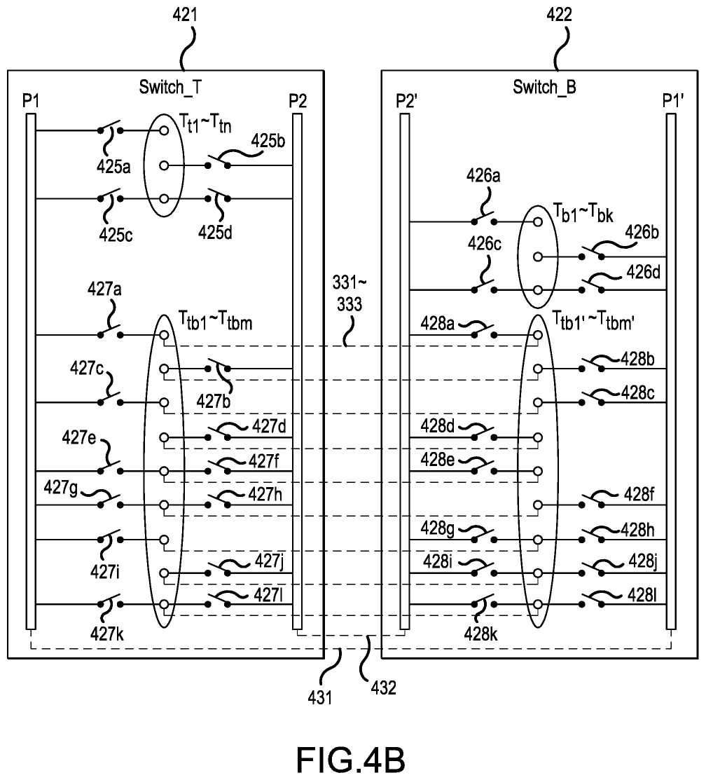

FIG. 4A is a simplified cross-sectional view of an RF switch module for an illustrative double-pole, multi-throw switch, including an RF switch IC divided between top and bottom sides of the PCB, according to a representative embodiment. FIG. 4B is a simplified circuit diagram showing potential switch element configurations for first and second switch ICs of the divided RF switch IC, according to a representative embodiment.

Referring to FIG. 4A, RF switch module 400 includes a multiple layer PCB 410 and a double-pole, multi-throw RF switch IC 420, which is divided into two portions including a first switch IC 421 arranged on a first side 411 (e.g., top surface) of the PCB 410 and a second switch IC 422 arranged on a second side 412 (e.g., bottom surface) of the PCB 410, opposite the first side 411. Each of the first switch IC 421 and the second switch IC 422 is a double-pole, multi-throw switch, as described below. The RF switch module 400 may be connected to additional circuitry, such as system mother board 260, for example, as discussed above with reference to other embodiments.

In the depicted embodiment, the double-pole is provided by first pole connections P1, P1′ and second pole connections P2, P2′. A first pole connection P1 on the first side 411 and another first pole connection P r on the second side 412 of the PCB 410 are electrically connected by a pole-via 431 passing through the PCB 410 between the first pole connection P1 and the another pole first connection P1′. A second pole connection P2 on the first side 411 and another second pole connection P2′ on the second side 412 of the PCB 410 are electrically connected by a pole-via 432 passing through the PCB 410 between the second pole connection P2 and the another second pole connection P2′. The first pole connections P1, P1′ are connected to the second pad 251, and the second pole connections P2, P2′ are connected to the second pad 253 for the sake of illustration.

Further, in the depicted embodiment, the multiple throws are provided by one or more throw connections on each of the first and second sides 411 and 412 of the PCB 410, including one or more isolated throw connections on only the first or second side 411 or 412, and one or more linked throw connections having throw connections on both the first and second sides 411 and 412 joined through the PCB 410 by throw-vias, respectively. For example, the RF switch module 400 may have representative throw connections Tt1, Tt2 . . . Ttn and Ttb1, Ttb2 . . . Ttbm on the first side 411 and additional throw connections Tb1, Tb2 . . . Tbk and Ttb1′, Ttb2′ . . . Ttbm′ on the second side 412 of the PCB 410, where each of m, n and k is a positive integer greater than or equal to 1.

In the depicted embodiment, as in FIG. 3A, none of the throw connections Tt1, Tt2 . . . Ttn and Tb1, Tb2 . . . Tbk is connected to another throw connection by a through via in the PCB 410. However, the throw connections Ttb1, Ttb1′ are connected by the throw-via 331, the throw connections Ttb2, Ttb2′ are connected by the throw-via 332, and the throw connections Ttbm, Ttbm′ are connected by the throw-via 333, for example, as discussed above. Also, in the depicted embodiment, the throw connections Ttb1, Ttb1′, the throw connections Ttb2, Ttb2′ and the throw connections Ttbm, Ttbm′ are physically aligned with one another (e.g., aligned in the y direction), respectively, on the first and second sides 411 and 412 of the PCB 410, and the connecting throw-vias 331, 332 and 333 are effectively straight lines, as discussed above. However, each set of the throw connections Ttb1, Ttb1′, Ttb2, Ttb2′ and Ttbm, Ttbm′ may be offset diagonally from one another, without departing from the scope of the present teachings.

The first switch IC 421 of the divided RF switch IC 420 includes first switching elements for selectively connecting the throw connections Tt1, Tt2 . . . Ttn and the throw connections Ttb1, Ttb2 . . . Ttbm to the first and second pole connections P1 and P2 on the first side 411. Similarly, the second switch IC 422 of the divided RF switch IC 420 includes second switching elements for selectively connecting the throw connections Tb1, Tb2 . . . Tbk and Ttb1,′ Ttb2′ . . . Ttbm′ to the first and second pole connections P1 and P2 on the second side 412.

Referring to FIG. 4B, the potential (optional) switch element configurations for each of the throw connections Tt1, Tt2 . . . Ttn of the first switch IC 421 are shown by representative switch elements 425a, 425b, 425c and 425d. That is, each of the throw connections Tt1, Tt2 . . . Ttn may be implemented in the first switch IC 421 using the switch element 425a, using the switch element 425b, or using the switch elements 425c and 425d, to provide unique benefits for any particular situation or to meet application specific design requirements of various implementations, as would be apparent to one skilled in the art. The switch element 425a is configured to selectively connect the throw connections Tt1, Tt2 . . . Ttn to the first pole connection P1. The switch element 425b is configured to selectively connect the throw connections Tt1, Tt2 . . . Ttn to the second pole connection P2. The switch elements 425c and 425d are configured to selectively connect the throw connections Tt1, Tt2 . . . Ttn to the first pole connection P1, the second pole connection P2, or both.

Likewise, the potential switch element configurations for each of the throw connections Tb1, Tb2 . . . Tbk of the second switch IC 422 are shown by representative switch elements 426a, 426b and 426c. That is, as discussed above, each of the throw connections Tt1, Tt2 . . . Ttk may be implemented in the second switch IC 422 using the switch element 426a, using the switch element 426b, or using the switch elements 426c and 426d, to provide unique benefits for any particular situation or to meet application specific design requirements of various implementations, as would be apparent to one skilled in the art. The switch element 426a is configured to selectively connect the throw connections Tb1, Tb2 . . . Tbk to the second pole connection P2′. The switch element 426b is configured to selectively connect the throw connections Tb1, Tb2 . . . Tbk to the first pole connection Pr. The switch elements 426c and 426d are configured to selectively connect the throw connections Tb1, Tb2 . . . Tbk to the first pole connection P1′, the second pole connection P2′, or both.

FIG. 4B also shows the potential switch element configurations for each of the throw connections Ttb1, Ttb2 . . . Ttbm of the first switch IC 421 as shown by representative switch elements 427a, 427b, 427c, 427d, 427e, 427f, 427g, 427h, 427i, 427j, 427k and 4271 in the first switch IC 421, as well as the potential switch element configurations for each of the throw connections Ttb1′, Ttb2′ . . . Ttbm′ of the second switch IC 422 as shown by representative switch elements 428a, 428b, 428c, 428d, 428e, 428f, 428g, 428h, 428i, 428j, 428k and 4281in the second switch IC 422. As stated above, each of the throw connections Ttb1, Ttb2 . . . Ttbm and Ttb1′, Ttb2′ . . . Ttbm′ may be implemented according to one of the depicted potential switch element configurations to provide unique benefits for any particular situation or to meet application specific design requirements of various implementations, as would be apparent to one skilled in the art.

The switch elements 427a and 428a are configured to selectively connect the throw connections Ttb1, Ttb2 . . . Ttbm and Ttb1′, Ttb2′ . . . Ttbm′ to the first pole connection P1, the second pole connection P2′, or both. The switch elements 427b and 428b are configured to selectively connect the throw connections Ttb1, Ttb2 . . . Ttbm and Ttb1′, Ttb2′ . . . Ttbm′ to the second pole connection P2, the first pole connection P1′, or both. The switch elements 427c and 428c are configured to selectively connect the throw connections Ttb1, Ttb2 . . . Ttbm and Ttb1′, Ttb2′ . . . Ttbm′ to the first pole connection P1, the first pole connection P1′, or both. The switch elements 427d and 428d are configured to selectively connect the throw connections Ttb1, Ttb2 . . . Ttbm and Ttb1′, Ttb2′ . . . Ttbm′ to the second pole connection P2, the second pole connection P2′, or both.

The switch elements 427e, 427f and 428e are configured to selectively connect the throw connections Ttb1, Ttb2 . . . Ttbm and Ttb1′, Ttb2′ . . . Ttbm′ to the first pole connection P1, the second pole connection P2, the second pole connection P2′, or any combination thereof. The switch elements 427g, 427h and 428f are configured to selectively connect the throw connections Ttb1, Ttb2 . . . Ttbm and Ttb1′, Ttb2′ . . . Ttbm′ to the first pole connection P1, the second pole connection P2, the first pole connection P1′, or any combination thereof. The switch elements 427i, 428g and 428h are configured to selectively connect the throw connections Ttb1, Ttb2 . . . Ttbm and Ttb1′, Ttb2′ . . . Ttbm′ to the first pole connection P1, the second pole connection P2′, the first pole connection P1′, or any combination thereof. The switch elements 427j, 428i and 428j are configured to selectively connect the throw connections Ttb1, Ttb2 . . . Ttbm and Ttb1′, Ttb2′ . . . Ttbm′ to the second pole connection P2, the second pole connection P2′, the first pole connection P1′, or any combination thereof. The switch elements 427k, 4271, 428k and 428l are configured to selectively connect the throw connections Ttb1, Ttb2 . . . Ttbm and Ttb1′, Ttb2′ . . . Ttbm′ to the first pole connection P1, the second pole connection P2, the second pole connection P2′, the first pole connection P1′, or any combination thereof.

The throw connections Ttb1, Ttb2 . . . Ttbm are connected to the throw connections Ttb1′, Ttb2′ . . . Ttbm′ by the throw-vias 331, 332 and 333, respectively, indicated by dashed lines for ease of illustration. Also, the first pole connections P1, P1′ are connected by the pole-via 431 and the second pole connections P2, P2′ are connected by the pole-via 432, indicted by dashed lines, respectively.

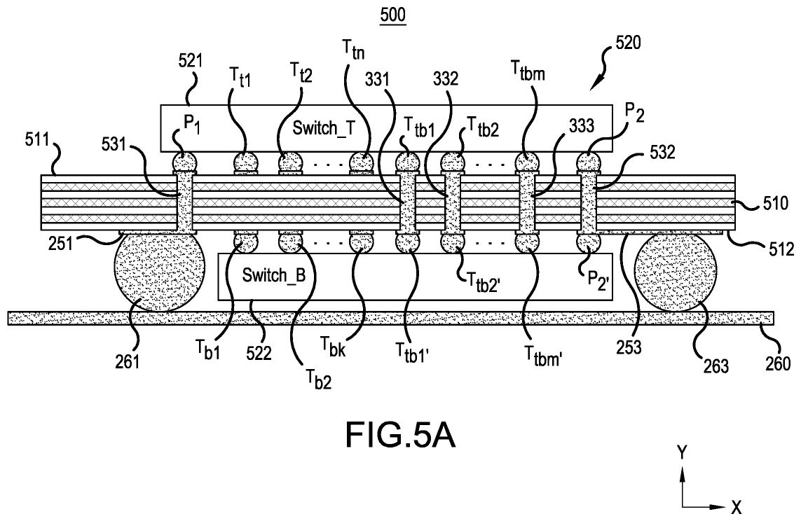

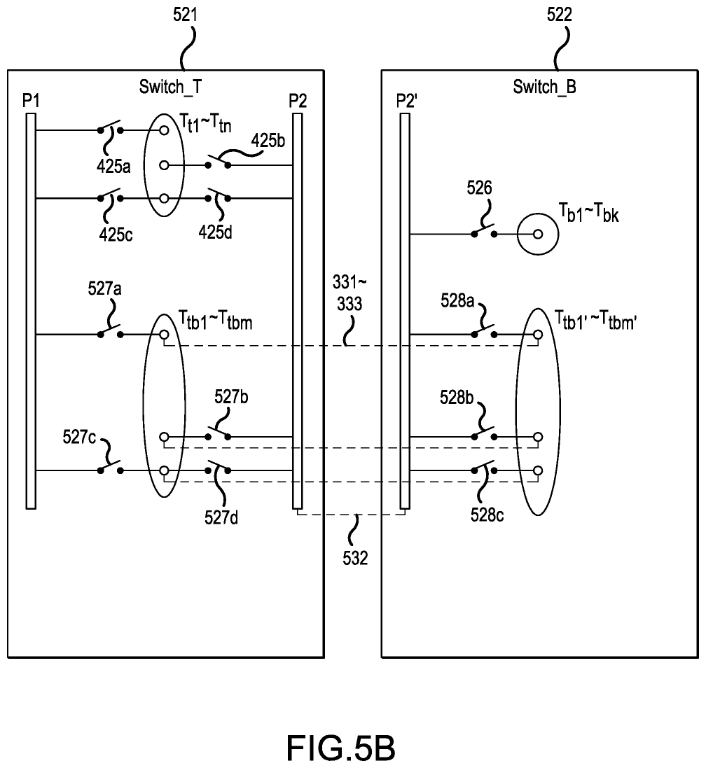

FIG. 5A is a simplified cross-sectional view of an RF switch module for an illustrative double-pole, multi-throw switch, including an RF switch IC divided between top and bottom sides of the PCB, according to a representative embodiment. FIG. 5B is a simplified circuit diagram showing potential switch element configurations for first and second switch ICs of the divided RF switch IC, according to a representative embodiment.

Referring to FIG. 5A, RF switch module 500 includes a multiple layer PCB 510 and a double-pole, multi-throw RF switch IC 520, which is divided into two portions including a first switch IC 521 arranged on a first side 511 (e.g., top surface) of the PCB 510 and a second switch IC 522 arranged on a second side 512 (e.g., bottom surface) of the PCB 510, opposite the first side 511. In the depicted embodiment, the first switch IC 521 is a double-pole, multi-throw switch, and the second switch IC 522 is a single-pole, multi-throw switch, as described below. The RF switch module 500 may be connected to additional circuitry, such as system mother board 260, for example, as discussed above with reference to other embodiments.

In the depicted embodiment, the double-pole of the first switch IC 521 is provided by first pole connection P1 and second pole connection P2, and the single-pole of the second switch IC 522 is provided by and second pole connections P2′. In an alternative embodiment, implementation may be reversed, such that the first switch IC 521 is configured to implement the single-pole and the second switch IC 522 is configured to implement the double-pole of the RF switch IC 520, without departing from the scope of the present teachings.

In FIG. 5A, a first pole connection P1 on the first side 511 is electrically connected by a pole-via 531 passing through the PCB 510 to the second pad 251 (which is connected to the solder ball 261) for the sake of illustration. A second pole connection P2 on the first side 511 and another second pole connection P2′ on the second side 512 of the PCB 510 are electrically connected by a pole-via 532 passing through the PCB 510 between the second pole connection P2 and the another second pole connection P2′. The second pole connections P2, P2′ are connected to the second pad 253 for the sake of illustration.

Further, in the depicted embodiment, the RF switch module 500 may have representative throw connections Tt1, Tt2 . . . Ttn and Ttb1, Ttb2 . . . Ttbm on the first side 511 and additional throw connections Tb1, Tb2 . . . Tbk and Ttb1′, Ttb2′ . . . Ttbm′ on the second side 512 of the PCB 510, for example, where each of m, n and k is a positive integer greater than or equal to 1. The arrangement of the representative throw connections Tt1, Tt2 . . . Ttn and Ttb1, Ttb2 . . . Ttbm on the first side 511 and the throw connections Tb1, Tb2 . . . Tbk and Ttb1′, Ttb2′ . . . Ttbm′ on the second side 512 of the PCB 510 is substantially the same as discussed above with reference to the RF switch modules 300 and 400, and therefore the description will not be repeated here.

The first switch IC 521 of the divided RF switch IC 520 includes first switching elements for selectively connecting the throw connections Tt1, Tt2 . . . Ttn and the throw connections Ttb1, Ttb2 . . . Ttbm to the first and second pole connections P1 and P2 on the first side 511. Similarly, the second switch IC 522 of the divided RF switch IC 520 includes second switching elements for selectively connecting the throw connections Tb1, Tb2 . . . Tbk and Ttb1,′ Ttb2′ . . . Ttbm′ to the second pole connections P2′ on the second side 512.

Referring to FIG. 5B, the potential switch element configurations for each of the throw connections Tt1, Tt2 . . . Ttn of the first switch IC 521 are shown by representative switch elements 425a, 425b, 425c and 425d, which are the same as discussed above with reference to FIG. 4B, and therefore the description will not be repeated here. The potential switch element configurations for each of the throw connections Tb1, Tb2 . . . Tbk of the second switch IC 522 are shown by representative switch element 526, which is configured to selectively connect the throw connections Tb1, Tb2 . . . Tbk to the second pole connection P2′.

FIG. 5B also shows the potential switch element configurations for each of the throw connections Ttb1, Ttb2 . . . Ttbm of the first switch IC 521 as shown by representative switch elements 527a, 527b, 527c, and 527d in the first switch IC 521, as well as the potential switch element configurations for each of the throw connections Ttb1′, Ttb2′ . . . Ttbm′ of the second switch IC 522 as shown by representative switch elements 528a, 528b, and 528c in the second switch IC 522. As stated above, each of the throw connections Ttb1, Ttb2 . . . Ttbm and Ttb1′, Ttb2′ . . . Ttbm′ may be implemented according to one of the depicted potential switch element configurations to provide unique benefits for any particular situation or to meet application specific design requirements of various implementations, as would be apparent to one skilled in the art.

The switch elements 527a and 528a are configured to selectively connect the throw connections Ttb1, Ttb2 . . . Ttbm and Ttb1′, Ttb2′ . . . Ttbm′ to the first pole connection P1, the second pole connection P2′, or both. The switch elements 527b and 528b are configured to selectively connect the throw connections Ttb1, Ttb2 . . . Ttbm and Ttb1′, Ttb2′ . . . Ttbm′ to the second pole connection P2, the second pole connection P2′, or both. The switch elements 527c, 527d and 528c are configured to selectively connect the throw connections Ttb1, Ttb2 . . . Ttbm and Ttb1′, Ttb2′ . . . Ttbm′ to the first pole connection P1, the second pole connection P2, the second pole connection P2′, or any combination thereof. The throw connections Ttb1, Ttb2 . . . Ttbm are connected to the throw connections Ttb1′, Ttb2′ . . . Ttbm′ by the throw-vias 331, 332 and 333, respectively, indicated by dashed lines for ease of illustration. Also, the second pole connections P2, P2′ are connected by the pole-via 532 and the second pole connections P2, P2′ are connected by the pole-via 432, indicted by dashed lines, respectively.

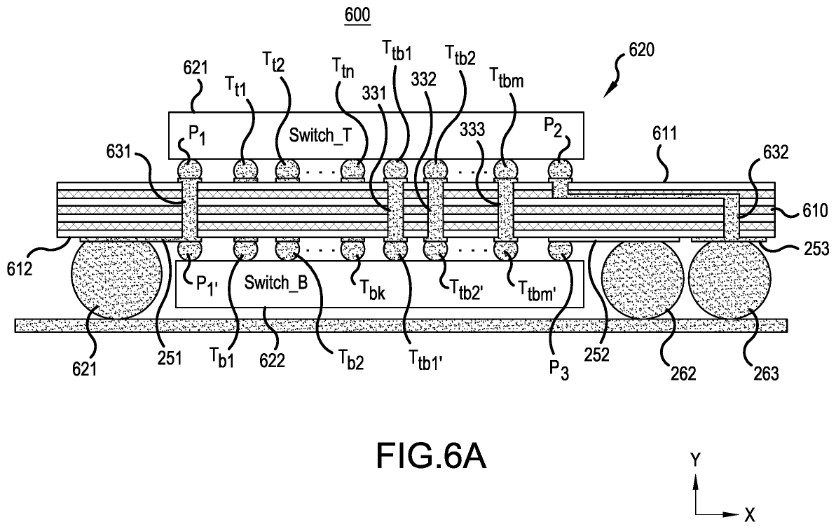

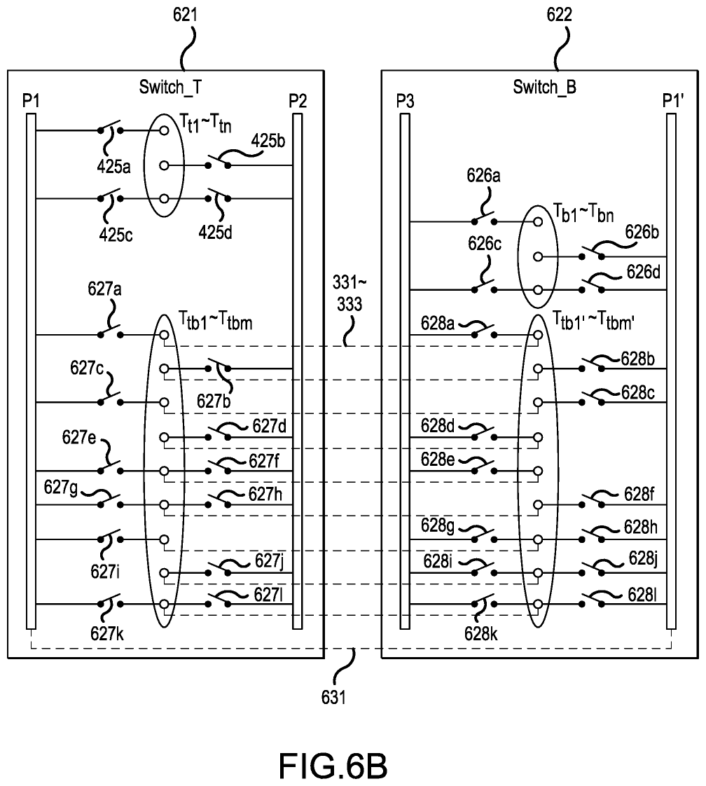

FIG. 6A is a simplified cross-sectional view of an RF switch module for an illustrative three-pole, multi-throw switch, including an RF switch IC divided between top and bottom sides of the PCB, according to a representative embodiment. FIG. 6B is a simplified circuit diagram showing potential switch element configurations for first and second switch ICs of the divided RF switch IC, according to a representative embodiment.

Referring to FIG. 6A, RF switch module 600 includes a multiple layer PCB 610 and a three-pole, multi-throw RF switch IC 620, which is divided into two portions including a first switch IC 621 arranged on a first side 611 (e.g., top surface) of the PCB 610 and a second switch IC 622 arranged on a second side 612 (e.g., bottom surface) of the PCB 610, opposite the first side 611. In the depicted embodiment, the first switch IC 621 is a double-pole, multi-throw switch, and the second switch IC 622 is a double-pole, multi-throw switch, as described below. The RF switch module 600 may be connected to additional circuitry, such as system mother board 260, for example, as discussed above with reference to other embodiments.

In the depicted embodiment, the double-pole of the first switch IC 621 is provided by first pole connection P1 and second pole connection P2, and the double-pole of the second switch IC 622 is provided by first pole connection P r and third pole connection P3. First pole connection P1 on the first side 611 and another first pole connection P r on the second side 612 are electrically connected by a pole-via 631 passing through the PCB 610, and are further connected to the second pad 251 (which is connected to the solder ball 261) for the sake of illustration. Second pole connection P2 on the first side 611 is electrically connected to the second pad 253 (which is connected to the solder ball 263), for the sake of illustration, by a pole-via 632 passing through the PCB 610. Third pole connection P3 on the second side 612 is electrically connected to the second pad 252 (which is connected to the solder ball 262), for the sake of illustration.

Further, in the depicted embodiment, the RF switch module 600 may have representative throw connections Tt1, Tt2 . . . Ttn and Ttb1, Ttb2 . . . Ttbm on the first side 611 and additional throw connections Tb1, Tb2 . . . Tbk and Ttb1′, Ttb2′ . . . Ttbm′ on the second side 612 of the PCB 610, for example, where each of m, n and k is a positive integer greater than or equal to 1. The arrangement of the representative throw connections Tt1, Tt2 . . . Ttn and Ttb1, Ttb2 . . . Ttbm on the first side 611 and the throw connections Tb1, Tb2 . . . Tbk and Ttb1′, Ttb2′ . . . Ttbm′ on the second side 612 of the PCB 610 is substantially the same as discussed above with reference to the RF switch modules 300 and 400, and therefore the description will not be repeated here.

The first switch IC 621 of the divided RF switch IC 620 includes first switching elements for selectively connecting the throw connections Tt1, Tt2 . . . Ttn and the throw connections Ttb1, Ttb2 . . . Ttbm to the first and second pole connections P1 and P2 on the first side 611. The second switch IC 622 of the divided RF switch IC 620 includes second switching elements for selectively connecting the throw connections Tb1, Tb2 . . . Tbk and Ttb1,′ Ttb2′ . . . Ttbm′ to the first pole connection P1′ and the third pole connection P3 on the second side 612.

Referring to FIG. 6B, the potential switch element configurations for each of the throw connections Tt1, Tt2 . . . Ttn of the first switch IC 621 are shown by representative switch elements 425a, 425b, 425c and 425d, which are the same as discussed above with reference to FIG. 4B, and therefore the description will not be repeated here. The potential switch element configurations for each of the throw connections Tb1, Tb2 . . . Tbk of the second switch IC 622 are shown by representative switch elements 626a, 626b, 626c and 626d. The switch element 626a is configured to selectively connect the throw connections Tb1, Tb2 . . . Tbk to the third pole connection P3. The switch element 626b is configured to selectively connect the throw connections Tb1, Tb2 . . . Tbk to the first pole connection Pr. The switch elements 626c and 626d are configured to selectively connect the throw connections Tb1, Tb2 . . . Tbk to the third pole connection P3, the first pole connection P1′, or both.

FIG. 6B also shows the potential switch element configurations for each of the throw connections Ttb1, Ttb2 . . . Ttbm of the first switch IC 621 as shown by representative switch elements 627a, 627b, 627c, 627d, 627e, 627f, 627g, 627h, 627i, 627j, 627k and 6271 in the first switch IC 621, as well as the potential switch element configurations for each of the throw connections Ttb1′, Ttb2′ . . . Ttbm′ of the second switch IC 622 as shown by representative switch elements 628a, 628b, 628c, 628d, 628e, 628f, 628g, 628h, 628i, 628j, 628k and 6281in the second switch IC 622. As stated above, each of the throw connections Ttb1, Ttb2 . . . Ttbm and Ttb1′, Ttb2′ . . . Ttbm′ may be implemented according to one of the depicted potential switch element configurations to provide unique benefits for any particular situation or to meet application specific design requirements of various implementations, as would be apparent to one skilled in the art.

The switch elements 627a and 628a are configured to selectively connect the throw connections Ttb1, Ttb2 . . . Ttbm and Ttb1′, Ttb2′ . . . Ttbm′ to the first pole connection P1, the third pole connection P3, or both. The switch elements 627b and 628b are configured to selectively connect the throw connections Ttb1, Ttb2 . . . Ttbm and Ttb1′, Ttb2′ . . . Ttbm′ to the second pole connection P2, the first pole connection P1′, or both. The switch elements 627c and 628c are configured to selectively connect the throw connections Tb1, Ttb2 . . . Ttbm and Ttb1′, Ttb2′ . . . Ttbm′ to the first pole connection P1, the first pole connection P1′, or both. The switch elements 627d and 628d are configured to selectively connect the throw connections Ttb1, Ttb2 . . . Ttbm and Ttb1′, Ttb2′ . . . Ttbm′ to the second pole connection P2, the third pole connection P3, or both.

The switch elements 627e, 627f and 628e are configured to selectively connect the throw connections Ttb1, Ttb2 . . . Ttbm and Ttb1′, Ttb2′ . . . Ttbm′ to the first pole connection P1, the second pole connection P2, the third pole connection P3, or any combination thereof. The switch elements 627g, 627h and 628f are configured to selectively connect the throw connections Ttb1, Ttb2 . . . Ttbm and Ttb1′, Ttb2′ . . . Ttbm′ to the first pole connection P1, the second pole connection P2, the first pole connection P1′, or any combination thereof. The switch elements 627i, 628g and 628h are configured to selectively connect the throw connections Ttb1, Ttb2 . . . Ttbm and Ttb1′, Ttb2′ . . . Ttbm′ to the first pole connection P1, the third pole connection P3, the first pole connection P1′, or any combination thereof. The switch elements 627j, 628i and 628j are configured to selectively connect the throw connections Ttb1, Ttb2 . . . Ttbm and Ttb1′, Ttb2′ . . . Ttbm′ to the second pole connection P2, the third pole connection P3, the first pole connection P1′, or any combination thereof. The switch elements 627k, 6271, 628k and 628l are configured to selectively connect the throw connections Ttb1, Ttb2 . . . Ttbm and Ttb1′, Ttb2′ . . . Ttbm′ to the first pole connection P1, the second pole connection P2, the third pole connection P3, the first pole connection P1′, or any combination thereof.

The throw connections Ttb1, Ttb2 . . . Ttbm are connected to the throw connections Ttb1′, Ttb2′ . . . Ttbm′ by the throw-vias 331, 332 and 333, respectively, indicated by dashed lines for ease of illustration. Also, the first pole connections P1, P1′ are connected by the pole-via 631, indicted by a dashed line.

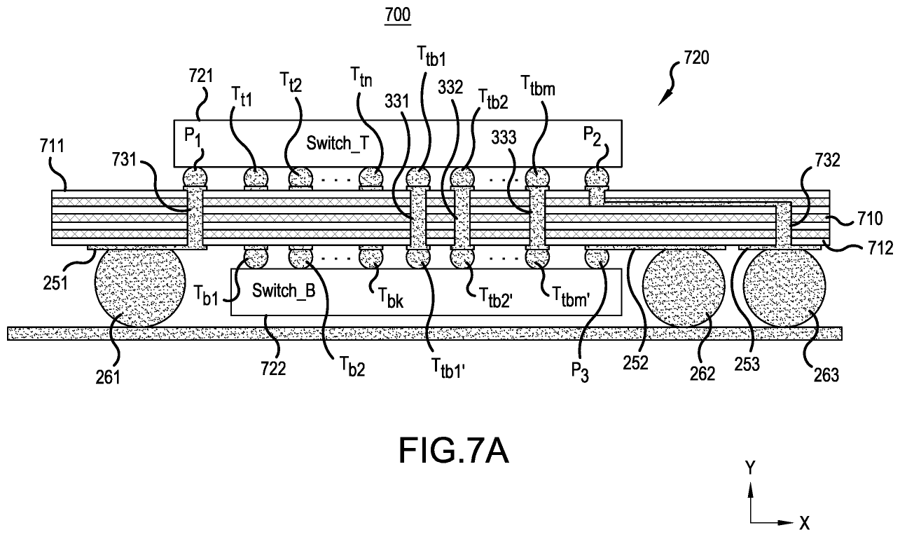

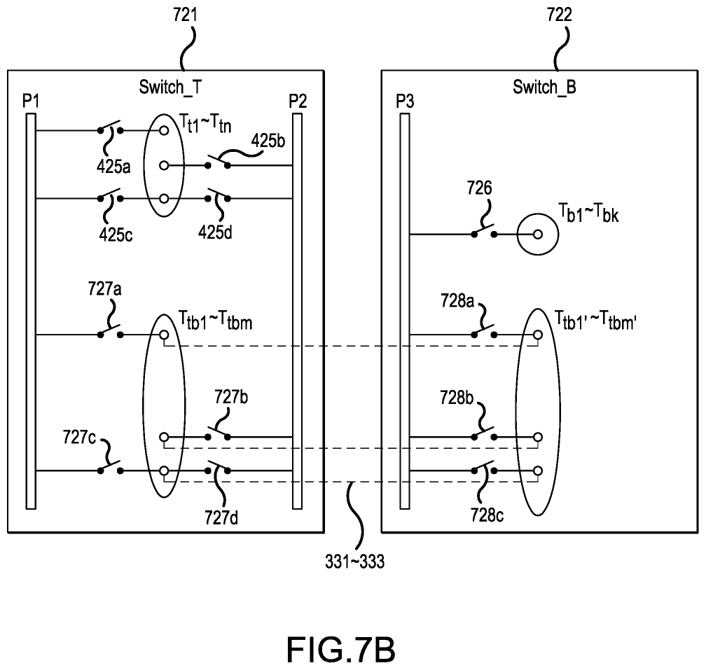

FIG. 7A is a simplified cross-sectional view of an RF switch module for an illustrative three-pole, multi-throw switch, including an RF switch IC divided between top and bottom sides of the PCB, according to a representative embodiment. FIG. 7B is a simplified circuit diagram showing potential switch element configurations for first and second switch ICs of the divided RF switch IC, according to a representative embodiment.

Referring to FIG. 7A, RF switch module 700 includes a multiple layer PCB 710 and a three-pole, multi-throw RF switch IC 720, which is divided into two portions including a first switch IC 721 arranged on a first side 711 (e.g., top surface) of the PCB 710 and a second switch IC 722 arranged on a second side 712 (e.g., bottom surface) of the PCB 710, opposite the first side 711. In the depicted embodiment, the first switch IC 721 is a double-pole, multi-throw switch, and the second switch IC 722 is a single-pole, multi-throw switch, as described below. The RF switch module 700 may be connected to additional circuitry, such as system mother board 260, for example, as discussed above with reference to other embodiments.

In the depicted embodiment, the double-pole of the first switch IC 721 is provided by first pole connection P1 and second pole connection P2, and the single-pole of the second switch IC 722 is provided by and third pole connection P3. In an alternative embodiment, implementation may be reversed, such that the first switch IC 721 is configured to implement the single-pole and the second switch IC 722 is configured to implement the double-pole of the RF switch IC 720, without departing from the scope of the present teachings.

First pole connection P1 on the first side 711 is electrically connected by a pole-via 731 passing through the PCB 710 to the second pad 251 (which is connected to the solder ball 261) for the sake of illustration. Second pole connection P2 on the first side 711 is electrically connected by a pole-via 732 passing through the PCB 710 to the second pad 253 (which is connected to the solder ball 263) for the sake of illustration. Third pole connection P3 on the second side 712 is electrically connected to the second pad 252 (which is connected to the solder ball 262) for the sake of illustration. The RF switch module 700 does not include pole-vias connecting terminals of the same pole on opposite sides of the PCB 710.

Further, in the depicted embodiment, the RF switch module 700 may have representative throw connections Tt1, Tt2 . . . Ttn and Ttb1, Ttb2 . . . Ttbm on the first side 711 and additional throw connections Tb1, Tb2 . . . Tbk and Ttb1′, Ttb2′ . . . Ttbm′ on the second side 712 of the PCB 710, for example, where each of m, n and k is a positive integer greater than or equal to 1. The arrangement of the representative throw connections Tt1, Tt2 . . . Ttn and Ttb1, Ttb2 . . . Ttbm on the first side 711 and the throw connections Tb1, Tb2 . . . Tbk and Ttb1′, Ttb2′ . . . Ttbm′ on the second side 712 of the PCB 710 is substantially the same as discussed above with reference to the RF switch modules 300 and 400, and therefore the description will not be repeated here.

The first switch IC 721 of the divided RF switch IC 720 includes first switching elements for selectively connecting the throw connections Tt1, Tt2 . . . Ttn and the throw connections Ttb1, Ttb2 . . . Ttbm to the first and second pole connections P1 and P2 on the first side 711. The second switch IC 722 of the divided RF switch IC 720 includes second switching elements for selectively connecting the throw connections Tb1, Tb2 . . . Tbk and Ttb1,′ Ttb2′ . . . Ttbm′ to the third pole connection P3 on the second side 712.

Referring to FIG. 7B, the potential switch element configurations for each of the throw connections Tt1, Tt2 . . . Ttn of the first switch IC 721 are shown by representative switch elements 425a, 425b, 425c and 425d, which are the same as discussed above with reference to FIG. 4B, and therefore the description will not be repeated here. The potential switch element configuration for each of the throw connections Tb1, Tb2 . . . Tbk of the second switch IC 722 are shown by representative switch element 726, which is configured to selectively connect the throw connections Tb1, Tb2 . . . Tbk to the third pole connection P3.

FIG. 7B also shows the potential switch element configurations for each of the throw connections Ttb1, Ttb2 . . . Ttbm of the first switch IC 721 as shown by representative switch elements 727a, 727b, 727c and 727d in the first switch IC 721, as well as the potential switch element configurations for each of the throw connections Ttb1′, Ttb2′ . . . Ttbm′ of the second switch IC 722 as shown by representative switch elements 7628a, 728b and 728c in the second switch IC 722. As stated above, each of the throw connections Ttb1, Ttb2 . . . Ttbm and Ttb1′, Ttb2′ . . . Ttbm′ may be implemented according to one of the depicted potential switch element configurations to provide unique benefits for any particular situation or to meet application specific design requirements of various implementations, as would be apparent to one skilled in the art.

The switch elements 727a and 728a are configured to selectively connect the throw connections Ttb1, Ttb2 . . . Ttbm and Ttb1′, Ttb2′ . . . Ttbm′ to the first pole connection P1, the third pole connection P3, or both. The switch elements 727b and 728b are configured to selectively connect the throw connections Ttb1, Ttb2 . . . Ttbm and Ttb1′, Ttb2′ . . . Ttbm′ to the second pole connection P2, the third pole connection P3, or both. The switch elements 727c, 727d and 728c are configured to selectively connect the throw connections Ttb1, Ttb2 . . . Ttbm and Ttb1′, Ttb2′ . . . Ttbm′ to the first pole connection P2, the second pole connection P2, the third pole connection P3, or any combination thereof. The throw connections Ttb1, Ttb2 . . . Ttbm are connected to the throw connections Ttb1′, Ttb2′ . . . Ttbm′ by the throw-vias 331, 332 and 333, respectively, indicated by dashed lines for ease of illustration.

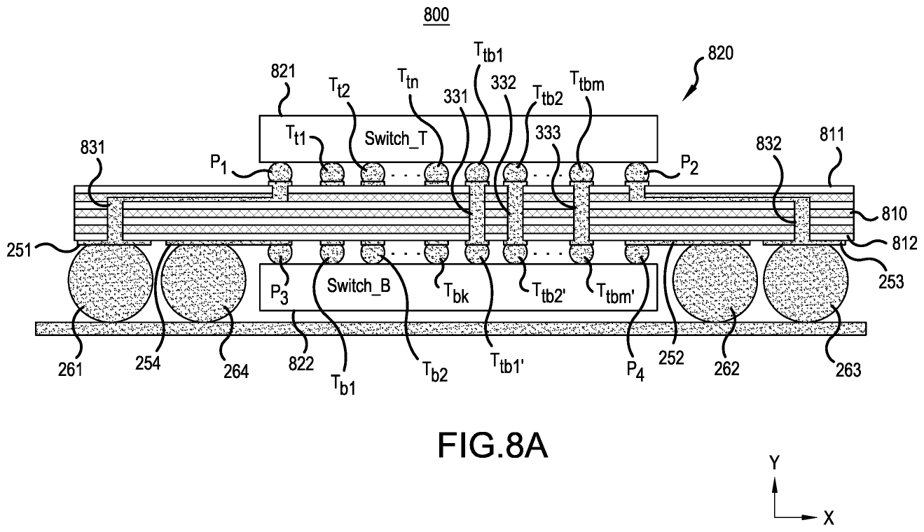

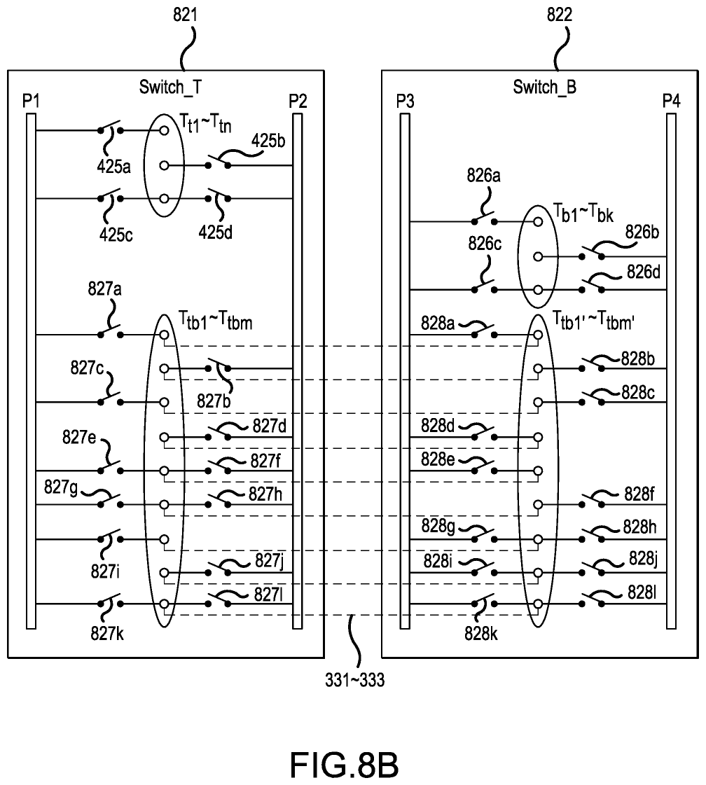

FIG. 8A is a simplified cross-sectional view of an RF switch module for an illustrative four-pole, multi-throw switch, including an RF switch IC divided between top and bottom sides of the PCB, according to a representative embodiment. FIG. 8B is a simplified circuit diagram showing potential switch element configurations for first and second switch ICs of the divided RF switch IC, according to a representative embodiment.

Referring to FIG. 8A, RF switch module 800 includes a multiple layer PCB 810 and a four-pole, multi-throw RF switch IC 820, which is divided into two portions including a first switch IC 821 arranged on a first side 811 (e.g., top surface) of the PCB 810 and a second switch IC 822 arranged on a second side 812 (e.g., bottom surface) of the PCB 810, opposite the first side 811. In the depicted embodiment, the first switch IC 821 is a double-pole, multi-throw switch, and the second switch IC 822 is a double-pole, multi-throw switch, as described below. The RF switch module 800 may be connected to additional circuitry, such as system mother board 260, for example, as discussed above with reference to other embodiments.

In the depicted embodiment, the double-pole of the first switch IC 821 is provided by first pole connection P1 and second pole connection P2, and the double-pole of the second switch IC 822 is provided by third pole connection P4 and fourth pole connection P4. First pole connection P1 on the first side 811 is electrically connected by a pole-via 831 passing through the PCB 810 to the second pad 251 (which is connected to the solder ball 261) for the sake of illustration. Second pole connection P2 on the first side 811 is electrically connected by a pole-via 832 passing through the PCB 810 to the second pad 253 (which is connected to the solder ball 263) for the sake of illustration. Third pole connection P3 on the second side 812 is electrically connected to the second pad 254 (which is connected to solder ball 264), for the sake of illustration. Fourth pole connection P4 on the second side 812 is electrically connected to the second pad 252 (which is connected to solder ball 262), for the sake of illustration.

Further, in the depicted embodiment, the RF switch module 800 may have representative throw connections Tt1, Tt2 . . . Ttn and Ttb1, Ttb2 . . . Ttbm on the first side 811 and additional throw connections Tb1, Tb2 . . . Tbk and Ttb1′, Ttb2′ . . . Ttbm′ on the second side 812 of the PCB 810, for example, where each of m, n and k is a positive integer greater than or equal to 1. The arrangement of the representative throw connections Tt1, Tt2 . . . Ttn and Ttb1, Ttb2 . . . Ttbm on the first side 811 and the throw connections Tb1, Tb2 . . . Tbk and Ttb1′, Ttb2′ . . . Ttbm′ on the second side 812 of the PCB 810 is substantially the same as discussed above with reference to the RF switch modules 300 and 400, and therefore the description will not be repeated here.

The first switch IC 821 of the divided RF switch IC 820 includes first switching elements for selectively connecting the throw connections Tt1, Tt2 . . . Ttn and the throw connections Ttb1, Ttb2 . . . Ttbm to the first and second pole connections P1 and P2 on the first side 811. The second switch IC 822 of the divided RF switch IC 820 includes second switching elements for selectively connecting the throw connections Tb1, Tb2 . . . Tbk and Ttb1,′ Ttb2′ . . . Ttbm′ to the third pole connection P3 and the fourth pole connection P4 on the second side 812.

Referring to FIG. 8B, the potential switch element configurations for each of the throw connections Tt1, Tt2 . . . Ttn of the first switch IC 821 are shown by representative switch elements 425a, 425b, 425c and 425d, which are the same as discussed above with reference to FIG. 4B, and therefore the description will not be repeated here. The potential switch element configurations for each of the throw connections Tb1, Tb2 . . . Tbk of the second switch IC 822 are shown by representative switch elements 826a, 826b, 826c and 826d. The switch element 826a is configured to selectively connect the throw connections Tb1, Tb2 . . . Tbk to the third pole connection P3. The switch element 826b is configured to selectively connect the throw connections Tb1, Tb2 . . . Tbk to the fourth pole connection P4. The switch elements 826c and 826d are configured to selectively connect the throw connections Tb1, Tb2 . . . Tbk to the third pole connection P3, the fourth pole connection P4, or both.

FIG. 8B also shows the potential switch element configurations for each of the throw connections Ttb1, Ttb2 . . . Ttbm of the first switch IC 821 as shown by representative switch elements 827a, 827b, 827c, 827d, 827e, 827f, 827g, 827h, 827i, 827j, 827k and 8271 in the first switch IC 821, as well as the potential switch element configurations for each of the throw connections Ttb1′, Ttb2′ . . . Ttbm′ of the second switch IC 822 as shown by representative switch elements 828a, 828b, 828c, 828d, 828e, 828f, 828g, 828h, 828i, 828j, 828k and 8281in the second switch IC 822. As stated above, each of the throw connections Ttb1, Ttb2 . . . Ttbm and Ttb1′, Ttb2′ . . . Ttbm′ may be implemented according to one of the depicted potential switch element configurations to provide unique benefits for any particular situation or to meet application specific design requirements of various implementations, as would be apparent to one skilled in the art.

The switch elements 827a and 828a are configured to selectively connect the throw connections Ttb1, Ttb2 . . . Ttbm and Ttb1′, Ttb2′ . . . Ttbm′ to the first pole connection P1, the third pole connection P3, or both. The switch elements 827b and 828b are configured to selectively connect the throw connections Ttb1, Ttb2 . . . Ttbm and Ttb1′, Ttb2′ . . . Ttbm′ to the second pole connection P2, the fourth pole connection P4, or both. The switch elements 827c and 828c are configured to selectively connect the throw connections Ttb1, Ttb2 . . . Ttbm and Ttb1′, Ttb2′ . . . Ttbm′ to the first pole connection P1, the fourth pole connection P4, or both. The switch elements 827d and 828d are configured to selectively connect the throw connections Ttb1, Ttb2 . . . Ttbm and Ttb1′, Ttb2′ . . . Ttbm′ to the second pole connection P2, the third pole connection P3, or both.

The switch elements 827e, 827f and 828e are configured to selectively connect the throw connections Ttb1, Ttb2 . . . Ttbm and Ttb1′, Ttb2′ . . . Ttbm′ to the first pole connection P1, the second pole connection P2, the third pole connection P3, or any combination thereof. The switch elements 827g, 827h and 828f are configured to selectively connect the throw connections Ttb1, Ttb2 . . . Ttbm and Ttb1′, Ttb2′ . . . Ttbm′ to the first pole connection P1, the second pole connection P2, the fourth pole connection P4, or any combination thereof. The switch elements 827i, 828g and 828h are configured to selectively connect the throw connections Ttb1, Ttb2 . . . Ttbm and Ttb1′, Ttb2′ . . . Ttbm′ to the first pole connection P1, the third pole connection P3, the fourth pole connection P4, or any combination thereof. The switch elements 827j, 828i and 828j are configured to selectively connect the throw connections Ttb1, Ttb2 . . . Ttbm and Ttb1′, Ttb2′ . . . Ttbm′ to the second pole connection P2, the third pole connection P3, the fourth pole connection P4, or any combination thereof. The switch elements 827k, 8271, 828k and 828l are configured to selectively connect the throw connections Ttb1, Ttb2 . . . Ttbm and Ttb1′, Ttb2′ . . . Ttbm′ to the first pole connection P1, the second pole connections P2, the third pole connection P3, the fourth pole connection P4, or any combination thereof.

The throw connections Ttb1, Ttb2 . . . Ttbm are connected to the throw connections Ttb1′, Ttb2′ . . . Ttbm′ by the throw-vias 331, 332 and 333, respectively, indicated by dashed lines for ease of illustration. None of the first through fourth pole connections P1 to P4 through the PCB 810 are interconnected by the pole-vias, respectively.

In various embodiments, the number and arrangement of poles and throws may vary without departing from the scope of the present teachings. For example, in each of the depicted embodiments, the number of isolated throws and linked throws is illustrative, and not otherwise limited by the number shown in the figures. The various components, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A radio frequency (RF) switch device, comprising:
a printed circuit board (PCB) having a first side and a second side opposite the first side;
at least one pole connection on each of the first side and the second side of the PCB;
at least one throw connection on each of the first side and the second side of the PCB;
a first switch integrated circuit (IC) comprising at least one first switching element for selectively connecting the at least one pole connection and the at least one throw connection on the first side of the PCB; and
a second switch IC comprising at least one second switching element for selectively connecting the at least one pole connection and the at least one throw connection on the second side of the PCB.

2. The RF switch device of claim 1, wherein the at least one pole connection on the first side of the PCB is connected by a pole-via through the PCB to the at least one pole connection on the second side of the PCB.

3. The RF switch device of claim 1, wherein the at least one throw connection on the first side of the PCB is connected by a throw-via through the PCB to the at least one throw connection on the second side of the PCB.

4. The RF switch device of claim 1, wherein the at least one pole connection on the first side of the PCB comprises first and second pole connections, and the at least one pole connection on the second side of the PCB comprises third and fourth pole connections, wherein the first, second, third and fourth pole connections are electrically separated from each other, providing a four pole switching device; and
wherein a throw connection of the at least one throw connection on the first side of the PCB and a corresponding throw connection of the at least one throw connection on the second side of the PCB are connected by a throw-via through the PCB.

5. The RF switch device of claim 4, wherein the first switch IC is a double-pole multi-throw switch circuit and the at least one first switching element is selectively connectable to at least one of the first connection and the second pole connection, and
wherein the second switch IC is a double-pole multi-throw switch circuit and the at least one second switching element is selectively connectable to at least one of the third pole connection and the fourth pole connection, providing a four-pole multi-throw RF switch device.

6. The RF switch device of claim 1, wherein the at least one pole connection on the first side of the PCB comprises a first pole connection and a second pole connection, and the at least one pole connection on the second side of the PCB comprises another first pole connection, electrically connected to the first pole connection by a pole-via through the PCB, and a third pole connection, wherein the second pole connection and the third pole connection are electrically separated from the each other.

7. The RF switch device of claim 6, wherein the first switch IC is a double-pole multi-throw switch circuit and the at least one first switching element is selectively connectable to at least one of the first and second pole connections, and
wherein the second switch IC is a double-pole multi-throw switch circuit and the at least one second switching element is selectively connectable to at least one of the another first pole connection and the third pole connection, providing a three-pole multi-throw RF switch device.

8. The RF switch device of claim 1, wherein the at least one pole connection on the first side of the PCB comprises a first pole connection and a second pole connection, and the at least one pole connection on the second side of the PCB comprises another first pole connection and another second pole connection respectively connected by a first pole-via and a second pole-via through the PCB to the first pole connection and the second pole connection on the first side of the PCB.

9. The RF switch device of claim 8, wherein the first switch IC is a double-pole multi-throw switch circuit and the at least one first switching element is selectively connectable to at least one of the first and second pole connections, and
wherein the second switch IC is a double-pole multi-throw switch circuit and the at least one second switching element is selectively connectable to at least one of the another first pole connection and the another second pole connection, providing a double-pole multi-throw RF switch device.

10. The RF switch device of claim 1, wherein the at least one pole connection on the first side of the PCB comprises a first pole connection and a second pole connection, and the at least one pole connection on the second side of the PCB comprises another first pole connection connected by a pole-via through the PCB to the first pole connection on the first side of the PCB.

11. The RF switch device of claim 10, wherein the first switch IC is a double-pole multi-throw switch circuit and the at least one first switching element is selectively connectable to at least one of the first and second pole connections, and
wherein the second switch IC is a single-pole multi-throw switch circuit and the at least one second switching element is selectively connectable to the another first pole connection, providing a double-pole multi-throw RF switch device.

12. The RF switch device of claim 1, wherein the at least one pole connection on the first side of the PCB comprises a first pole connection, and the at least one pole connection on the second side of the PCB comprises another first pole connection connected by a pole-via to the first pole connection on the first side of the PCB.

13. The RF switch device of claim 12, wherein the first switch IC is a single-pole multi-throw switch circuit and the at least one first switching element is selectively connectable to the first pole connection on the first side of the PCB, and
wherein the second switch IC is a single-pole multi-throw switch circuit and the at least one second switching element is selectively connectable to the another first pole connection on the second side of the PCB, providing a single-pole multi-throw RF switch device.

14. The RF switch device of claim 1, wherein the at least one pole connection comprises a first pole connection and a second pole connection on the first side of the PCB, and a third connection on the second side of the PCB, wherein the first, second and third pole connections are electrically separated from each other; and
wherein a throw connection of the at least one throw connection on the first side of the PCB and a corresponding throw connection of the at least one throw connection on the second side of the PCB are connected by a throw-via through the PCB.

15. The RF switch device of claim 14, wherein the first switch IC is a double-pole multi-throw switch circuit and the at least one first switching element is selectively connectable to at least one of the first and second pole connections, and
wherein the second switch IC is a single-pole multi-throw switch circuit and the at least one second switching element is selectively connectable to the third pole connection, providing a three-pole multi-throw RF switch device.

16. The RF switch device of claim 1, wherein the at least one pole connection comprises a first pole connection on the first side of the PCB and a second pole connection on the second side of the PCB, and
wherein a throw connection of the at least one throw connection on the first side of the PCB and a corresponding throw connection of the at least one throw connection on the second side of the PCB are connected by a throw-via through the PCB.

17. The RF switch device of claim 16, wherein the first switch IC is a single-pole multi-throw switch circuit and the at least one first switching element is selectively connectable to the first pole connection, and
wherein the second switch IC is a single-pole multi-throw switch circuit and the at least one second switching element is selectively connectable to the second pole connection, providing a double-pole multi-throw RF switch device.

18. A printed circuit board (PCB) of a radio frequency (RF) switch device, the PCB comprising:
a top pole connection and a top throw connection on a top side of the PCB; and
a bottom pole connection and a bottom throw connection on a bottom side of the PCB,
wherein the top pole connection and the bottom pole connection are connected by a pole-via through the PCB and/or the top throw connection and the bottom throw connection are selectively connected by a throw-via through the PCB.

19. The PCB of claim 18, wherein the top pole connection and the top throw connection are selectively connectable by a switching element in a first switch integrated circuit (IC) of the RF switch device, and wherein the bottom pole connection and the bottom throw connection are selectively connectable by a switching element in a second switch IC of the RF switch device.

20. A radio frequency (RF) switch device, comprising:
a printed circuit board (PCB) having a first side and a second side opposite the first side;
at least one pole connection on each of the first side and the second side of the PCB, the at least one pole connection on the first side being physically aligned with and electrically connected to the at least one throw connection on the second side of the PCB;
at least one throw connection on each of the first side and the second side of the PCB, the at least one throw connection on the first side being physically aligned with and electrically connected to the at least one throw connection on the second side of the PCB;
a first switch integrated circuit (IC) comprising at least one first switching element for selectively connecting the at least one throw connection on the first side of the PCB; and
a second switch IC comprising at least one second switching element for selectively connecting the at least one throw connection on the second side of the PCB.
